(19) United States
(12) Patent Application Publication
(10) Pub. No.: US 2013/0233245 A1
(43) Pub. Date: Sep. 12, 2013

(54) ELECTROSTATIC SPRAY PRINTING APPRATUS

(71) Applicants: Hee Yeop Chae, Seoul (KR); Won Tae Hwang, Bucheon-si (KR); Min Jun Jo, Suwon-si (KR)

(72) Inventors: Hee Yeop Chae, Seoul (KR); Won Tae Hwang, Bucheon-si (KR); Min Jun Jo, Suwon-si (KR)

(73) Assignee: Research & Business Foundation Sungkyunkwan University, Suwon-si (KR)

(21) Appl. No.: 13/722,035

(22) Filed: Dec. 20, 2012

(30) Foreign Application Priority Data
Dec. 27, 2011 (KR) 10-2011-0143182

(51) Int. Cl. B05B 5/053

(52) U.S. Cl. CPC B05B 5/0533
USPC 118/624; 239/690

(57) ABSTRACT

An electrostatic spray printing apparatus includes a nozzle, a first voltage supply, and two guide electrodes. The nozzle sprays a solution containing an organic material. The first voltage supply divides the solution sprayed from the nozzle into fine droplets by applying a positive voltage to the nozzle. The guide electrodes are arranged to be spaced apart from each other with an end of the nozzle therebetween, extends in a first direction, and are grounded. The electrostatic spray printing apparatus forms an organic pattern with a uniform thickness.

### CROSS-REFERENCE TO RELATED APPLICATION

This application claims priority to and the benefit of Korean Patent Application No. 2011-0143182, filed on Dec. 27, 2011, the disclosure of which is incorporated herein by reference in its entirety.

### BACKGROUND

1. Field of the Invention

The present invention relates to an electrostatic spray printing apparatus, and more particularly, to an electrostatic spray printing apparatus for forming an organic pattern.

2. Discussion of Related Art

Currently, ink-jet printing technology, nozzle printing technology, and electrostatic spray printing technology are attracting attention as methods of forming an organic light-emitting layer in a large-area organic light-emitting panel. In the case of the ink-jet printing technology, a nozzle clogging problem, etc. is more likely to occur. In case of the nozzle printing technology, it is difficult to form a fine pattern. Accordingly, among the described technologies, the electrostatic spray printing technology is particularly prominent.

In general, an electrostatic spray printing apparatus is a spraying device for dividing a liquid into fine droplets using only an electric force, and due to the simple shape and structure of its nozzle, it is easily fabricated and can generate droplets having a size of several hundreds of nanometers to several tens of micrometers. In addition, the electrostatic spray printing apparatus may generate charged fine droplets having a monodispersed distribution.

However, even when the organic light-emitting layer is formed using the electrostatic spray printing apparatus, there is a problem in that the thickness of the organic light-emitting layer formed in each pixel is not uniform. Therefore, various studies have been conducted to solve such non-uniformity in thickness of the organic light-emitting layer.

### SUMMARY OF THE INVENTION

The present invention is directed to an electrostatic spray printing apparatus through which an organic pattern having a uniform thickness is formed.

According to an aspect of the present invention, there is provided an electrostatic spray printing apparatus, including a nozzle spraying a solution containing an organic material, a first voltage supply dividing the solution sprayed from the nozzle into fine droplets by applying a positive voltage to the nozzle, and two guide electrodes arranged to be spaced apart from each other with an end of the nozzle therebetween, extending in a first direction, and grounded.

The electrostatic spray printing apparatus may further include a conductive mask arranged under the two guide electrodes, having a linear opening extending in a direction intersecting the two guide electrodes, and to which a positive voltage is applied.

The electrostatic spray printing apparatus may further include a second voltage supply applying the positive voltage to the conductive mask.

The nozzle, the two guide electrodes, and the conductive mask may be combined with each other.

Each of the two guide electrodes may be a bar shape having a quadrangular or circular cross section, or a plate shape facing the other with the nozzle therebetween.

According to another aspect of the present invention, there is provided an electrostatic spray printing apparatus including a nozzle spraying a solution containing an organic material, a first voltage supply dividing the solution sprayed from the nozzle into fine droplets by applying a positive voltage to the nozzle, and two guide electrodes arranged to be spaced apart from each other with an end of the nozzle therebetween, extending in a first direction, and to which a negative voltage is applied.

The electrostatic spray printing apparatus may further include a second voltage supply applying the negative voltage to the guide electrodes.

### BRIEF DESCRIPTION OF THE DRAWINGS

The above and other objects, features, and advantages of the present invention will become more apparent to those of ordinary skill in the art by describing in detail exemplary embodiments thereof with reference to the accompanying drawings, in which:

FIG. 1 is a conceptual diagram for describing an electrostatic spray printing apparatus according to an exemplary embodiment of the present invention;

FIGS. 2A to 2C are perspective views for describing exemplary embodiments of a guide electrode part illustrated in FIG. 1;

FIG. 3 is a perspective view for describing a mask part illustrated in FIG. 1;

FIG. 4 is a photograph of a pattern formed by applying a mask part having a linear opening with the width of about 1 mm;

FIG. 5A is a diagram for describing an electrostatic spray printing apparatus applied to a method of forming a pattern according to an exemplary embodiment of the present invention;

FIG. 5B is a diagram for describing an electrode pattern formed on a substrate illustrated in FIG. 5A;

FIG. 6 is optical microscope images of a thin film pattern (a) before printing, and (b) after printing;

FIG. 7 is a cross-sectional view of a thin film; and

FIG. 8 is a diagram showing a difference in thickness of a thin film.

### DETAILED DESCRIPTION OF EXEMPLARY EMBODIMENTS

Exemplary embodiments of the present invention will be described in detail below with reference to the accompanying drawings. While the present invention is shown and described in connection with exemplary embodiments thereof, it will be apparent to those skilled in the art that various modifications can be made without departing from the spirit and scope of the invention. Rather, these embodiments are provided so that this disclosure is thorough and complete and fully conveys the inventive concept to those skilled in the art. In the drawings, the sizes of layers and regions may be exaggerated for clarity.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the teachings of the present inventive concept.

The terminology used herein is for the purpose of describing particular embodiments only and is not intended to be limiting of the present inventive concept. As used herein, the singular forms “a,” “an,” and “the” are intended to include the plural forms as well, unless the context clearly indicates otherwise. It will be further understood that the terms “include” and/or “have” when used in this specification, specify the presence of stated features, integers, steps, operations, elements, components, and/or groups thereof but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### <Electrostatic Spray Printing Apparatus>

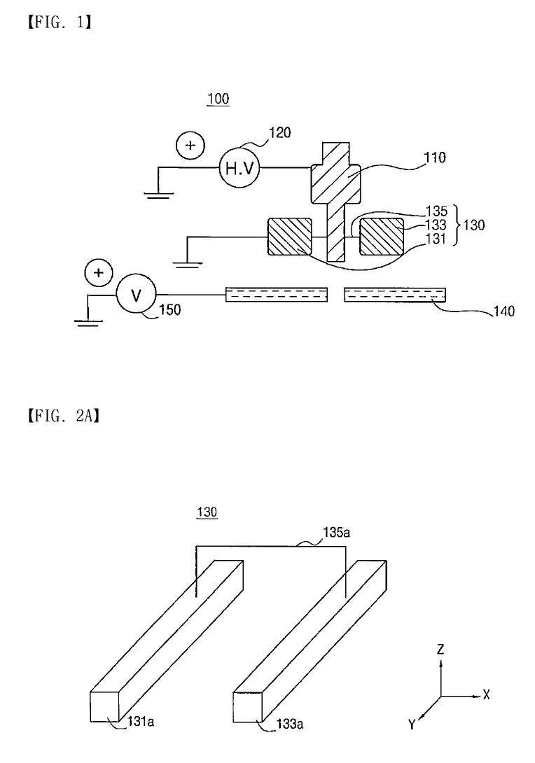

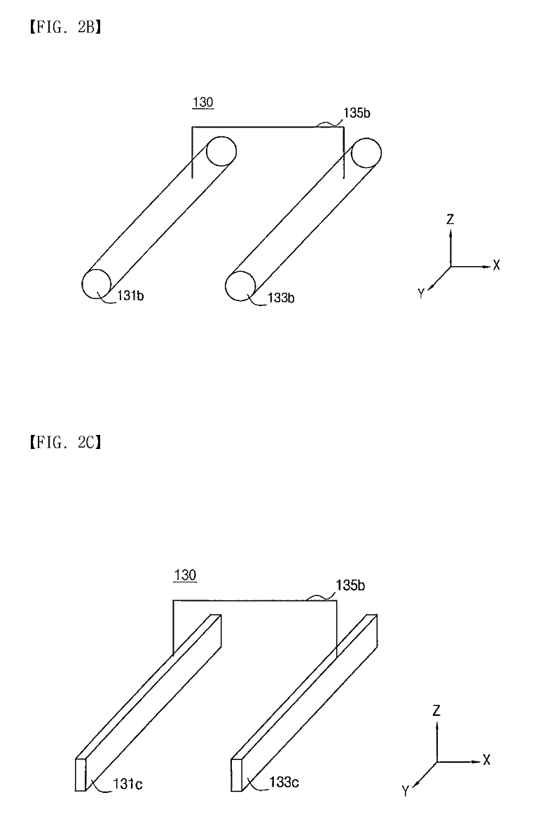

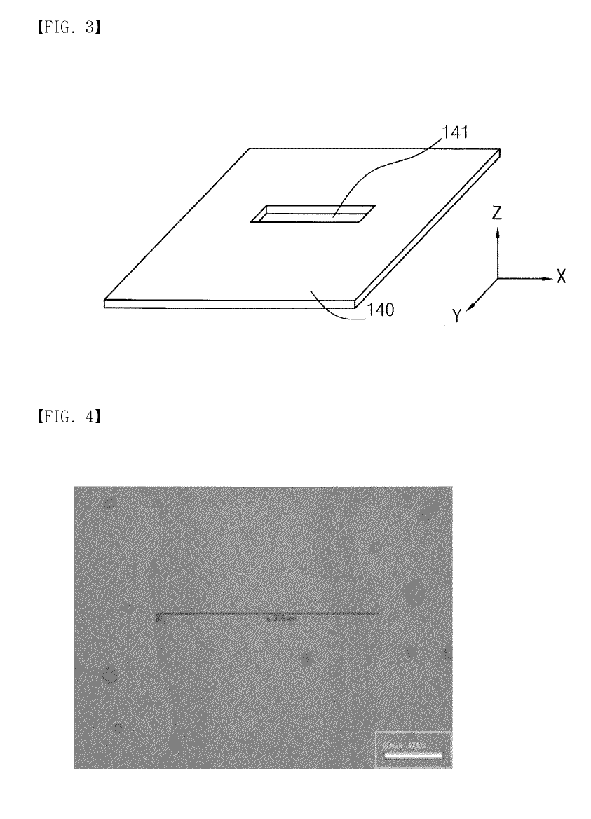

FIG. 1 is a conceptual diagram for describing an electrostatic spray printing apparatus according to an exemplary embodiment of the present invention, FIGS. 2A to 2C are perspective views for describing exemplary embodiments of a guide electrode part illustrated in FIG. 1, and FIG. 3 is a perspective view for describing a mask part illustrated in FIG. 1.

Referring to FIG. 1, an electrostatic spray printing apparatus 100 according to an exemplary embodiment of the present invention may include a nozzle part 110, a first voltage supply 120, a guide electrode part 130, a mask part 140, and a second voltage supply 150.

The nozzle part 110 may include one or more nozzle 110 for spraying a solution containing an organic material to an object substrate. The organic material may include, for example, an organic light emitting material. The nozzle 110 may be fabricated from a conductive material, for example, stainless steel, and have a shape of a micro-channel tube having constant inner and outer diameters.

The first voltage supply 120 applies a constant positive voltage to the nozzle 110. According to the positive voltage applied to the nozzle 110, the solution released from the nozzle 110 may be divided into droplets having ions with a corresponding polarity to be sprayed to a substrate (not shown). For example, when a positive voltage is applied to the nozzle 110, negative ions existing in the solution flowing into the nozzle 110 may move to a wall of the nozzle 110, and positive ions may be pushed to a meniscus of the solution. At this time, as the positive voltage applied to the nozzle 110 increases, the electric force which acts on the meniscus of the solution and the repulsive force between the positive ions may become greater than the surface tension of the solution, and therefore the meniscus of the solution forms a cone shape at the end portion of the nozzle, which is known as a cone-jet mode. Here, the cone-shaped meniscus of the solution is called a liquid cone, and a liquid jet is formed in a linear shape by a surface tangential stress at the end of the liquid cone. At the end of the liquid jet, the liquid jet may break into droplets having a predetermined size, for example, tens of nanometers (nm) to tens of micrometers (μm) by a disturbance of a surface wave applied on a surface of the liquid jet, and the broken droplets may be sprayed onto the substrate. As described above, when the first voltage supply 120 applies a constant positive voltage to the nozzle 110, the solution sprayed through the nozzle 110 may break into fine droplets charged with positive polarity to be sprayed to the substrate.

The guide electrode part 130 may control a spraying zone of the droplets sprayed from the nozzle 110. For this purpose, the guide electrode part 130 may include two guide electrodes 131 and 133 which are located adjacent to the nozzle 110, extending in a direction X in parallel, and spaced apart from each other by a predetermined interval with the nozzle 110 therebetween, and a connection line 135 electrically connecting the two guide electrodes 131 and 133. The two guide electrodes 131 and 133 may be formed of an electrically conductive material, and electrically connected to each other by the connection line 135. In addition, it is desirable that the two guide electrodes 131 and 133 have the same shape. The shape of each of the guide electrodes 131 and 133 is not particularly limited. Each of the guide electrodes 131 and 133 may have various shapes, for example, a bar shape having a cross section of a circle, a polygon, a semicircle, and an oval, or a plate shape. For example, as illustrated in FIG. 2A, each of the guide electrodes 131 and 133 may have a bar shape having a square cross section which is perpendicular to the substrate, and extending in a parallel direction Y to the substrate. Otherwise, as illustrated in FIG. 2B, each of the guide electrodes 131 and 133 may have a bar shape having a circular cross section which is perpendicular to the substrate, and extending in a parallel direction Y to the substrate. Still otherwise, as illustrated in FIG. 2C, the guide electrodes 131 and 133 may have plate shapes which are perpendicular to the substrate and facing each other with the nozzle 110 therebetween.

The droplets sprayed from the nozzle 110 are generally sprayed in such a way that a cross section parallel to the substrate is a circular shape. Such droplets that are sprayed in the circular shape may become sprayed in oval or linear shapes extending in a direction X by the guide electrode part 130.

In an exemplary embodiment of the present invention, as shown in FIG. 1, the two guide electrodes 131 and 133 may be grounded in order to spray the droplets in oval or linear shapes extending in a direction X. The grounded guide electrodes 131 and 133 may attract the droplets charged with positive polarity due to voltage difference from the nozzle 110 to which a positive voltage is applied, in a direction of the guide electrodes 131 and 133. That is, an attractive force may act between the grounded guide electrodes 131 and 133 and the droplets. Accordingly, the droplets sprayed in the circular shape may become sprayed in oval or linear shape having a long axis in a direction X intersecting the guide electrodes 131 and 133, for example, in a direction X perpendicular to the guide electrodes 131 and 133.

In other exemplary embodiment of the present invention, unlike as shown in FIG. 1, a negative voltage may be applied to the two guide electrodes 131 and 133 in order to spray the droplets in oval or linear shapes extending in a direction X. In this case, the electrostatic spray printing apparatus 100 may further include a separate voltage supply (not shown) which applies a negative voltage to the guide electrodes 131 and 133. The guide electrodes 131 and 133 to which the negative voltage is applied may attract the droplets charged with positive polarity due to voltage difference from the nozzle 110 to which a positive voltage is applied, in a direction of the guide electrodes 131 and 133. That is, an attractive force may act between the grounded guide electrodes 131 and 133 to which the negative voltage is applied and the droplets charged to the positive voltage. As a result, the droplets sprayed in the circular shape may be sprayed in an oval or linear shape having a long axis in a direction X intersecting the guide electrodes 131 and 133, for example, in a perpendicular direction X to the guide electrodes 131 and 133.

The mask part 140 is located between the substrate (not shown) and the guide electrode part 130, and formed of an electrically conductive material. As illustrated in FIG. 3, the mask part 140 may include a linear type opening 141 extending in a direction X intersecting the guide electrodes 131 and 133. A width and length of the opening 141 formed in the mask part 140 may be controlled when necessary.

The second voltage supply 150 may apply a positive voltage to the mask part 140. When the positive voltage is applied to the mask part 140 by the second voltage supply 150, an electric field may be formed in the mask part 140, and a repulsive force may act between the droplets passing through the opening 141 of the mask part 140 by the electric field. As a result, the droplets passing through the opening 141 of the mask part 140 may be sprayed to a narrower region than the opening 141.

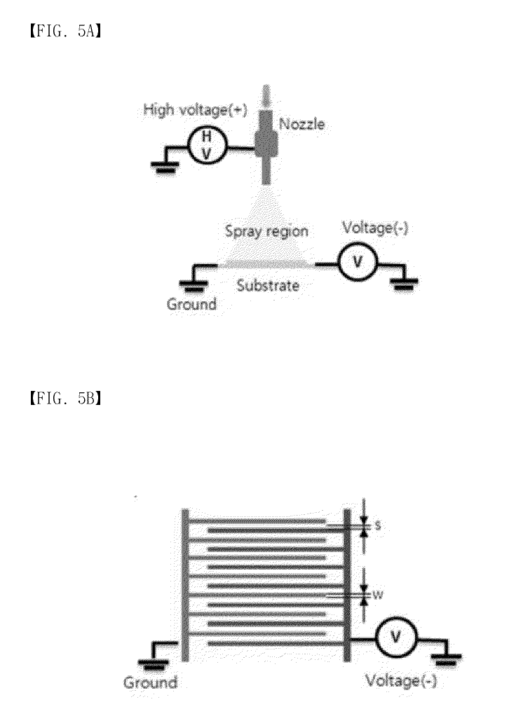

FIG. 4 is a photograph of a pattern formed by applying a mask part having an opening with the width of about 1 mm.

Referring to FIG. 4, even though the width of the opening 141 formed in the mask part 140 is about 1 mm, the width of the pattern formed by applying the mask part 140 is only about 315 μm. That is, when the mask part 140 is applied, it is easy to form a pattern having a micro-scale fine width.

The nozzle part 110, the guide electrode part 130, and the mask part 140 may be combined. That is, the nozzle part 110, the guide electrode part 130, and the mask part 140 may be combined and move together with respect to a fixed substrate. In contrast, the substrate may move while the nozzle part 110, the guide electrode part 130, and the mask part 140 are fixed.

### <Exemplary Embodiment>

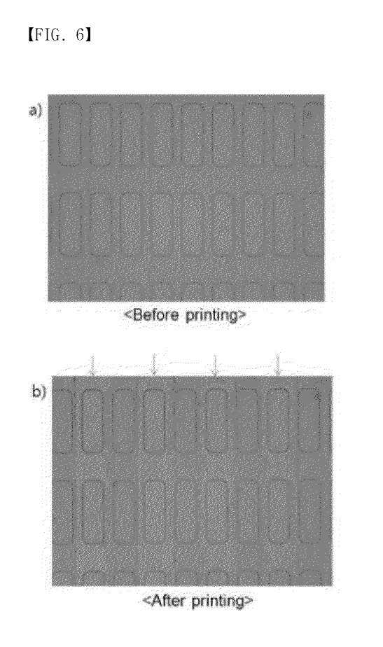

An organic pattern was formed using the electrostatic spray printing apparatus illustrated in FIG. 5. FIG. 5A is a diagram for describing an electrostatic spray printing apparatus applied to a method of forming a pattern according to an exemplary embodiment of the present invention, and FIG. 5B is a diagram for describing an electrode pattern formed on a substrate illustrated in FIG. 5A.

Referring to FIGS. 5A and 5B, an organic solution was formed using a low molecular material including 2-TNATA:TPBi:Ir(piq)2-acac and dichlorobenzene.

Serrated first and second electrodes, as illustrated in FIG. 5B, were formed to be staggered on a substrate in order to apply a voltage difference to the substrate. Patterned indium tin oxide (ITO) was used as the electrode. The width w of the ITO pattern was about 100 μm, and the space s between the ITO patterns was about 50 μm. A ground voltage was applied to the first electrode, and a voltage of about −5 kilovolt (kV) was applied to the second electrode. A voltage of about 3 kV was applied to a nozzle in order to divide the droplets formed in the end of the nozzle. The organic solution was sprayed through the nozzle at a speed of about 10 μL/min. The nozzle having an inner diameter of about 100 μm was used. A distance between the end of the nozzle and the substrate was maintained at approximately 3 to 4 cm.

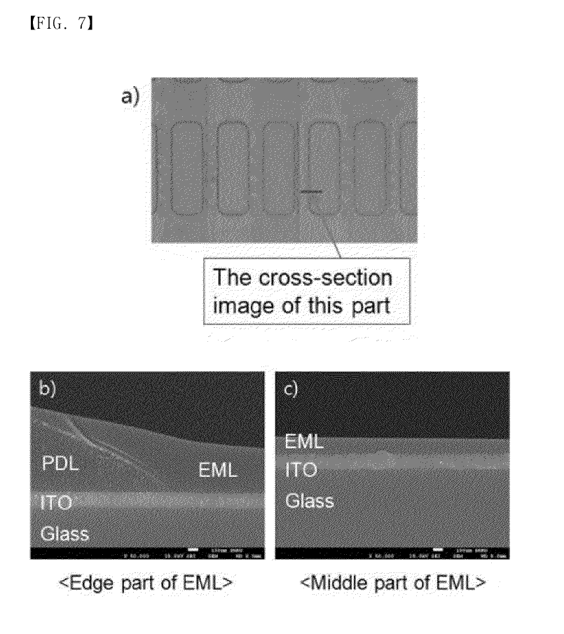

FIG. 6 is optical microscope images of a thin film pattern (a) before printing, and (b) after printing. The thin film illustrated in FIG. 6 was formed through a process in which a mask was not used.

Referring to FIG. 6, the organic thin film was deposited only on the second electrode to which a low voltage was applied, and was not deposited on the first electrode to which a ground voltage was applied. That is, in the process in which a mask was not used, since a potential difference was applied to the substrate and the droplets were charged with positive polarity by a high voltage applied to the nozzle, it was apparent that the organic thin film was successfully deposited.

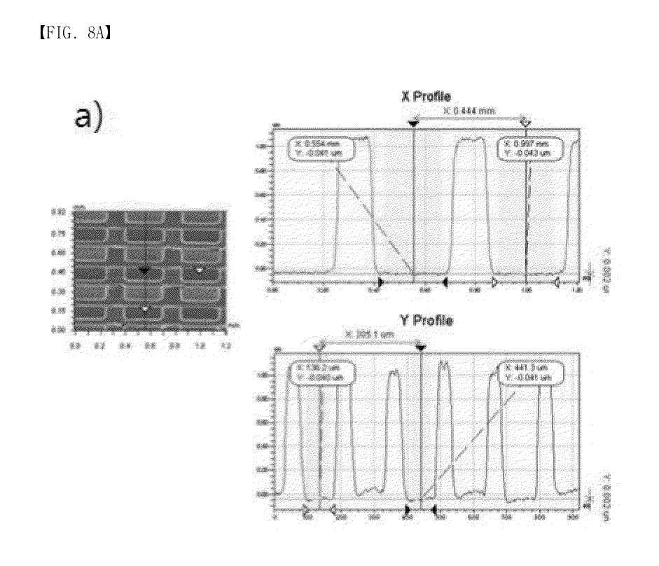

In order to check the profile of the thin film, a cross section of the thin film was investigated as illustrated in FIG. 7. The edge of the thin film was about three times thicker than the center of the thin film.

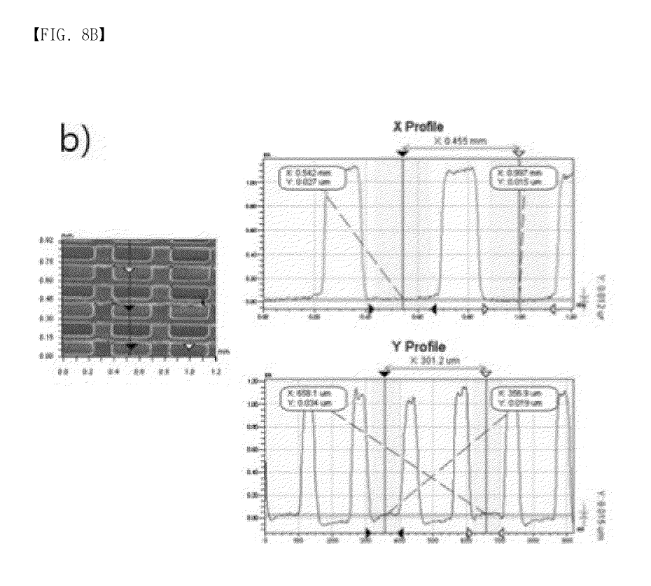

One of the important parameters for commercial mass production of an OLED panel is a uniformity of each pixel. The difference in thickness should be less than about 5 mm to meet the demand of the display industry. The uniformity was confirmed by a 3D-profiler. FIG. 8 shows the difference in thickness of the thin film. The thickness of bare ITO was first checked as illustrated in FIG. 8A in order to confirm the reliability of the measuring device, and then the thickness of the thin film was checked. The difference in thickness of the bare ITO was about 2 nm regardless of the direction, while the difference in thickness of the organic thin film was about 12 nm in a direction of X-profile and about 15 nm in a direction of Y-profile.

As described above, since the electrostatic spray printing apparatus according to the present invention has a guide electrode part, the droplets sprayed in circular shapes may become sprayed in oval or linear shapes having a long axis extending in a direction, and thereby an organic pattern having a uniform thickness may be formed

In addition, since the electrostatic spray printing apparatus according to the present invention has a conductive mask part, an organic pattern having a micro-scale fine width may be easily formed.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. An electrostatic spray printing apparatus, comprising:
a nozzle configured to spray a solution containing an organic material;
a first voltage supply configured to divide the solution sprayed from the nozzle into fine droplets by applying a positive voltage to the nozzle; and
two guide electrodes arranged to be spaced apart from each other with an end of the nozzle therebetween, configured to extend in a first direction, and grounded.

2. The electrostatic spray printing apparatus of claim 1, further comprising:
a conductive mask arranged under the two guide electrodes, including a linear opening extending in a direction intersecting the two guide electrodes, and to which a positive voltage is applied.

3. The electrostatic spray printing apparatus of claim 2, further comprising:
a second voltage supply configured to apply the positive voltage to the conductive mask.

4. The electrostatic spray printing apparatus of claim 3, wherein the nozzle, the two guide electrodes, and the conductive mask are combined with each other.

5. The electrostatic spray printing apparatus of claim 1, wherein each of the two guide electrodes is a bar shape having a quadrangular or circular cross section, or a plate shape facing the other with the nozzle therebetween.

6. An electrostatic spray printing apparatus, comprising:
a nozzle configured to spray a solution containing an organic material;
a first voltage supply configured to divide the solution sprayed from the nozzle into fine droplets by applying a positive voltage to the nozzle; and
two guide electrodes arranged to be spaced apart from each other with an end of the nozzle therebetween, configured to extend in a first direction, and to which a negative voltage is applied.

7. The electrostatic spray printing apparatus of claim 6, further comprising:
a second voltage supply configured to apply the negative voltage to the guide electrodes.
